(19) United States
(12) Patent Application Publication
(10) Pub. No.: US 2022/0275518 A1
(43) Pub. Date: Sep. 1, 2022

(54) Method for preparing a protective coating on a surface of key components and parts of IC devices based on plasma spraying technology and cold spraying technology

(71) Applicant: SHENYANG FORTUNE PRECISION EQUIPMENT CO., LTD, Shenyang, Liaoning (CN)

(72) Inventors: Guangwen Zheng, Shenyang, Liaoning (CN); Tianying Xiong, Sshenyang, Liaoning (CN); Yanfang Shen, Shenyang,Liaoning (CN); Xinyu Cui, Shenyang, Liaoning (CN); Jigiang Wang, Shenyang, Liaoning (CN); Junrong Tang, Shenyang, Liaoning (CN); Ning Li, Shenyang, Liaoning (CN); Jianzhong Qi, Shenyang, Liaoning (CN); Yongshan Tao, Shenyang, Liaoning (CN)

(21) Appl. No.: 17/631,810

(22) PCT Filed: Jan. 13, 2020
(86) PCT No.: PCT/CN2020/071775

§ 371 Date: Jan. 31, 2022

(30) Foreign Application Priority Data
Aug. 5, 2019 (CN) 201910716325.2

(51) Int. Cl. C23C 28/00; C23C 4/06; C23C 4/134; C23C 24/04

(52) U.S. Cl. CPC C23C 28/345; C23C 4/06; C23C 4/134; C23C 24/04

(57) ABSTRACT

Through the plasma spraying technology and the cold spraying high-speed deposition technology, an evenly distributed protective coating is formed on the surface of a plasma etching chamber. The protective coating, having a double-layer composite structure, includes a metal+Y₂O₃ coating as a metal+Y₂O₃ transition layer deposited by plasma spraying as a lower layer of the double-layer composite structure, and a high-purity Y₂O₃ ceramic coating coated on the metal+Y₂O₃ transition layer as an upper layer of the double-layer composite structure, the metal+Y₂O₃ transition layer is configured to reduce the difference in expansion coefficient between the Y₂O₃ ceramic coating and the metal substrate, and enhance the bonding force between the Y₂O₃ ceramic coating and the metal substrate; the high-purity Y₂O₃ ceramic coating is formed by depositing Y₂O₃ ceramic powders on the metal+Y₂O₃ transition layer at high speed through cold spraying high-speed deposition.

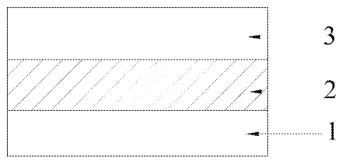

### CROSS REFERENCE OF RELATED APPLICATION

This is a U.S. National Stage under 35 U.S.C 371 of the International Application PCT/CN2020/071775, filed Jan. 13, 2020, which claims priority under 35 U.S.C. 119(a-d) to CN 201910716325.2, filed Aug. 5, 2019.

### BACKGROUND OF THE PRESENT INVENTION

### Field of Invention

The present invention relates to the preparation technology of ceramic coating, and more particularly to a method for preparing a protective coating on a surface of key components and parts of an IC (integrated circuit) device based on plasma spraying technology and cold spraying technology, which belongs to the field of semiconductor integrated circuit chip (wafer) plasma etching.

### Description of Related Arts

In the etching manufacturing device (such as a device for manufacturing semiconductor materials and liquid crystal displays) of IC equipment, it is necessary to resist the etching effect of high-energy plasma, so that when the substrate material is unable to meet the protection requirements, a protective coating is prepared on the surface of the substrate material to extend the service life thereof. High-purity alumina and high-purity yttria have been widely used as anti-plasma erosion materials due to their excellent resistance to plasma erosion. Research on the relative performance of the coating under different plasma energies shows that the high-purity yttria coating has better plasma erosion resistance than the high-purity alumina coating. The performance of yttria coating is slightly lower than that of yttria sintered block, but with the increase of plasma energy, the difference in performance between the two is gradually reduced. Therefore, with the continuous increase of plasma energy under actual working conditions, the yttria coating has also been more widely used.

The preparation method of high-purity yttria coating by thermal spraying technology includes steps of heating yttria ceramic powders to above 2000° C. to be in a molten state, and then obtaining a ceramic coating by highly depositing on a substrate material. The preparation conditions are harsh and expensive. Moreover, the outermost layer of the coating has transverse cracks and is not dense enough, so the coating needs to be improved in quality.

Plasma spraying is a relatively mature technology in thermal spraying. In plasma spraying process, after being injected into the high-temperature plasma jet, metal or non-metal powders are accelerated and sprayed at high speed onto the surface of the pre-treated workpiece in a molten or semi-melted state under the action of a high-speed jet, and then a coating with certain properties and functions is formed by layer-by-layer deposition. The ceramic coating prepared by plasma spraying has both technical and commercial advantages in solving the problem of plasma erosion resistance of IC equipment. Firstly, there is no limit to the size of processing devices during the process of preparing the coating. Secondly, the coating has relatively high plasma erosion resistance. Thirdly, the coating with a thickness up to several hundred microns is able to be prepared through plasma spraying. However, the coating prepared by plasma spraying also has certain defects, such as high porosity, which will affect the service life of the coating if used directly as a protective coating. Therefore, it is considered to deposit a layer of high-purity Y₂O₃ protective coating with higher density on the surface of the plasma sprayed ceramic coating. The high-purity Y₂O₃ protective coating deposited at high speed by cold spraying is combined with the high-purity plasma sprayed Y₂O₃ coating and the metal+Y₂O₃ coating by plasma spraying, so as to obtain a new protective coating against plasma erosion.

The basic principle of cold spraying technology is that the supersonic air flow carries spray powders to hit the surface of the substrate material at a very high speed (usually in a range of 400-1200 m/s), so that strong plastic deformation occurs on the surface of the substrate material and the spray powders are deposited on the surface of the substrate to form a coating. Due to the high deposition rate, the microstructure of the cold spraying coating is different from that of the plasma spraying coating, and the density of the cold spraying coating is higher than that of the plasma spraying coating. When the ceramic coating is prepared by cold spraying technology, the properties of the ceramic powders used are critical. Ordinary nano-powders are not suitable for preparing the cold spraying coating, because the high-pressure high-speed air flow of cold spraying will form bow shock waves on the surface of the substrate, which hinders the deposition of nano-powders. Moreover, when the particle size of powders to be sprayed is too large, the substrate will be eroded, so that it is difficult to form a coating.

At present, research on the protective coating of the plasma etching chamber of IC equipment focuses on the ceramics and composite coating based on yttria. Seok et al. (Seok H W, Kim Y C, Chol E Y, et al. Multi-component thermal spray coating material and production method and coating method thereof. U.S. Ser. No. 13/915,976[P]. 2013-06-12.) prepare several corrosion resistant coatings by atmospheric plasma spraying, such as Al₂O₃ coating, Y₂O₃ coating, multiple Y₂O₃—ZrO₂ composite coatings with different Y₂O₃ contents, and Y₂O₃—ZrO₂-Al₂O₃ composite coating, and test the corrosion rate of these coatings. It is concluded that the corrosion rate of the Y₂O₃—ZrO₂ composite coatings is basically smaller than that of the Y₂O₃ coating, and when a mass content ratio of Y₂O₃ to ZrO₂ in the Y₂O₃—ZrO₂ composite coating is 70:30, the corrosion rate of the Y₂O₃—ZrO₂ composite coating is the smallest and about 5 nm/min, that is, the plasma corrosion resistance is the best. However, there is a big difference between the thermal expansion coefficient of the ceramic coating and that of the metal substrate, which leads to the decrease of matching and bonding strength of the two, and affects the mechanical properties and corrosion resistance of the coating. Therefore, the metal+ceramics coating is used to be the bottom and transition layer to reduce the difference in the thermal expansion coefficient between the ceramic coating and the metal substrate, so as to further improve the overall mechanical properties and corrosion resistance of the coating.

### SUMMARY OF THE PRESENT INVENTION

Aiming at deficiencies of the prior art, an object of the present invention is to provide a method for preparing a protective coating on a surface of key components and parts of an IC (integrated circuit) device based on plasma spraying technology and cold spraying technology, which solves the problem that the current protective coating of plasma etching chamber of IC devices is prone to failure during high-power etching, and provides a new effective way to prepare the protective coating on the surface of the plasma etching chamber of IC devices, so as to obtain practical applications as soon as possible.

To achieve the above object, the present invention adopts technical solutions as follows:

A method for preparing a protective coating on a surface of key components and parts of an IC (integrated circuit) device based on plasma spraying technology and cold spraying technology adopts the plasma spraying technology and cold spraying high-speed deposition technology to form an evenly distributed protective coating on a surface of a plasma etching chamber of the IC device, wherein the protective coating, having a double-layer composite structure, comprises a metal+Y₂O₃ transition layer deposited by plasma spraying as a lower layer of the double-layer composite structure, and a high-purity Y₂O₃ ceramic coating coated on the metal+Y₂O₃ transition layer as an upper layer of the double-layer composite structure, the high-purity Y₂O₃ ceramic coating is formed by depositing Y₂O₃ ceramic powders on the metal+Y₂O₃ transition layer at high speed through cold spraying high-speed deposition. The method comprises steps of drying metal powders and Y₂O₃ powders, respectively, and then obtaining a metal+Y₂O₃ layer by depositing the metal and Y₂O₃ powders on a substrate at high speed through supersonic plasma spraying technology, and then depositing high-purity Y₂O₃ powders on the metal+Y₂O₃ layer through cold spraying high-throughout deposition technology, so as to obtain the protective coating through controlling process parameters.

Accordingly, a method for preparing a protective coating on a surface of key components and parts of an IC device based on plasma spraying technology and cold spraying technology comprises steps of:

(1) drying metal powders to be sprayed and Y₂O₃ powders to be sprayed, respectively, wherein a purity of the metal powders and the Y₂O₃ powders is above 99.9 wt. %;

(2) preparing a metal+Y₂O₃ transition layer on a substrate through plasma spraying technology, which comprises:

placing the dried metal and Y₂O₃ powders into a powder feeder of a plasma spraying device, obtaining mixed powders after evenly mixing the dried metal and Y₂O₃ powders, melting and depositing the mixed powders on an inner surface of a plasma etching chamber through the plasma spraying technology, so as to obtain the metal+Y₂O₃ transition layer; and

(3) depositing a high-purity Y₂O₃ coating through cold spraying high-speed deposition technology, which is specifically embodied as depositing high-purity Y₂O₃ powders through the cold spraying high-speed deposition technology on the metal+Y₂O₃ transition layer obtained by the step (2), so as to obtain the high-purity Y₂O₃ coating,

whereby, a (metal+Y₂O₃)/Y₂O₃ composite protective coating, namely, the protective coating is obtained.

Preferably, in the method for preparing the protective coating on the surface of the key components and parts of the IC device based on the plasma spraying technology and the cold spraying technology, the metal powders are at least one member selected from a group consisting of aluminum powders and yttrium powders.

Preferably, in the method for preparing the protective coating on the surface of the key components and parts of the IC device based on the plasma spraying technology and the cold spraying technology, a particle size of the metal powders and the Y₂O₃ powders is in a range of 1-50 μm.

Preferably, in the step (2) of the method for preparing the protective coating on the surface of the key components and parts of the IC device based on the plasma spraying technology and the cold spraying technology, the mixed powders are directly sprayed on the inner surface of the plasma etching chamber through the plasma spraying technology, and simultaneously plasma spraying parameters are controlled, wherein main working gas used in the plasma spraying technology is argon, secondary working gas is hydrogen, powder feeding gas is nitrogen, and gas flow rates thereof are in a range of 10-80 mL/min, 5-220 mL/min and 5-80 mL/min, respectively; a spraying distance is in a range of 10-100 mm, so that the mixed powders are deposited on the inner surface of the plasma etching chamber, so as to obtain the evenly distributed (metal+Y₂O₃) transition coating.

Preferably, in the step (3) of the method for preparing the protective coating on the surface of the key components and parts of the IC device based on the plasma spraying technology and the cold spraying technology, the high-purity Y₂O₃ powders are deposited on the metal+Y₂O₃ transition layer obtained by the step (2) through the cold spraying high-speed deposition technology, and simultaneously cold spraying parameters are controlled, wherein compressed air is used as working gas, a temperature of the compressed air is in a range of 200 to 700° C., a pressure of the compressed air is in a range of 1.5 to 3.0 MPa, and a spraying distance is in a range of 10 to 60 mm, so that the high-purity Y₂O₃ powders are deposited on the metal+Y₂O₃ transition layer, so as to obtain the evenly distributed high-purity Y₂O₃ protective coating.

Preferably, in the method for preparing the protective coating on the surface of the key components and parts of the IC device based on the plasma spraying technology and the cold spraying technology, a porosity of the protective coating is below 2%, an interface bonding strength of the protective coating and the substrate is in a range of 20 to 100 MPa, and a thickness of the protective coating is in a range of 10 to 400 μm.

The design idea of the present invention is described as follows.

The metal+Y₂O₃ transition layer is prepared on the key components and parts of the IC device through plasma spraying technology for reducing the huge difference in expansion coefficient between the Y₂O₃ ceramic coating and the metal substrate, and enhancing the bonding force between the Y₂O₃ ceramic coating and the metal substrate. And then, the high-purity Y₂O₃ coating is deposited on the metal+Y₂O₃ transition layer through cold spraying high-speed deposition technology for fully maintaining the crystal form and excellent properties of Y₂O₃.

Through the plasma spraying technology and the cold spraying high-speed deposition technology, an evenly distributed protective coating is formed on the surface of the plasma etching chamber. The protective coating, having a double-layer composite structure, comprises a metal+Y₂O₃ transition layer deposited by plasma spraying as a lower layer of the double-layer composite structure, and a high-purity Y₂O₃ ceramic coating coated on the metal+Y₂O₃ transition layer as an upper layer of the double-layer composite structure, the metal+Y₂O₃ transition layer is configured to reduce the difference in expansion coefficient between the Y₂O₃ ceramic coating and the metal substrate, and enhance the bonding force between the Y₂O₃ ceramic coating and the metal substrate; the high-purity Y₂O₃ ceramic coating is formed by depositing Y₂O₃ ceramic powders on the metal+Y₂O₃ transition layer at high speed through cold spraying high-speed deposition. The present invention adopts the plasma spraying technology to prepare the metal+ceramics coating as the transition layer on the etching chamber of the IC device, and then adopts the cold spraying high-speed deposition technology to deposit the high-purity and high-density Y₂O₃ coating on the metal+ceramics coating, so as to obtain the (metal+Y₂O₃)/Y₂O₃ composite coating, which has better plasma erosion resistance and protective effect.

The present invention has some advantages and beneficial effects as follows.

(1) The present invention adopts the plasma spraying technology to prepare the metal+ceramics coating as the transition layer on the etching chamber of the IC device, and then adopts the cold spraying high-speed deposition technology to deposit the high-purity and high-density Y₂O₃ coating on the metal+ceramics coating, so as to obtain the (metal+Y₂O₃)/Y₂O₃ composite coating, which has better plasma erosion resistance and protective effect.

(2) In the present invention, through the plasma spraying technology and the cold spraying high-speed deposition technology, a (metal+Y₂O₃)/Y₂O₃ composite coating with a thickness in a range of 100-400 μm is prepared as a protective coating on the inner surface of the plasma etching chamber of the IC device. The method provided by the present invention has high deposition efficiency, the thickness of the (metal+Y₂O₃)/Y₂O₃ composite coating is able to be designed according to actual usage for preparing a thick protective coating of the plasma etching chamber of the IC device.

### BRIEF DESCRIPTION OF THE DRAWINGS

The drawing is a schematic diagram of a (metal+Y₂O₃)/Y₂O₃ composite coating.

In the drawing, 1: substrate; 2: metal+Y₂O₃ transition layer; 3: high-purity Y₂O₃ coating.

### DETAILED DESCRIPTION OF THE PREFERRED EMBODIMENT

In the specific embodiments provided by the present invention, metal powders and Y₂O₃ powders are mixed in accordance with a weight ratio in a range of (0.1-5):1. After the mixture is dried, micron mixed powders with a particle size in a range of 1-50 μm are obtained. The above-mentioned micron mixed powders and high-purity Y₂O₃ powders are preheated by heated compressed air and then deposited on an inner surface of a plasma etching chamber by plasma spraying technology or cold spraying technology in order of priority, so that a protective coating is obtained on the inner surface of the plasma etching chamber. The plasma spraying technology is specifically described as follows: when the main working gas is argon, the secondary working gas is hydrogen, and the powder feeding gas is nitrogen, gas flow rates thereof are in a range of 10-80 mL/min, 5-220 mL/min and 5-80 mL/min, respectively; a spraying distance is in a range of 10-100 mm. The cold spraying technology is specifically described as follows: the compressed air is used as working gas, a temperature of the compressed air is in a range of 200−700° C., a pressure of the compressed air is in a range of 1.5-3.0 MPa, and a spraying distance is in a range of 10-60 mm.

The present invention is further detailed described in combination with embodiments as follows.

### First Embodiment

According to the first embodiment of the present invention, a method for preparing a protective coating on a 6061 aluminum alloy substrate for protecting an inner surface of a plasma etching chamber of an IC (integrated circuit) device comprises steps of:

(1) weighing 20 g of pure Al powders and 160 g of pure Y₂O₃ powders, mixing the pure Al powders with the Y₂O₃ powders, obtaining mixed micron (Al+Y₂O₃) powders after drying, weighing 300 g of high-purity Y₂O₃ powders with a purity of 99.99 wt. %, and drying the high-purity Y₂O₃ powders;

(2) preparing a (Al+Y₂O₃) coating with a thickness of 150 μm as a (Al+Y₂O₃) transition layer on the 6061 aluminum alloy substrate through plasma spraying technology by taking the mixed micron (Al+Y₂O₃) powders obtained by the step (1) as a raw material; and

(3) depositing a high-purity Y₂O₃ coating with a thickness of 180 μm on the (Al+Y₂O₃) transition layer obtained by the step (2) through cold spraying high-speed deposition technology by taking the dried high-purity Y₂O₃ powders obtained by the step (1) as a raw material, so that a (Al+Y₂O₃)/Y₂O₃ composite coating as the protective coating is obtained.

In the step (2) of preparing the (Al+Y₂O₃) transition layer through plasma spraying technology, main working gas is argon, secondary working gas is hydrogen, powder feeding gas is nitrogen, and gas flow rates thereof are 30 mL/min, 220 mL/min and 30 mL/min, respectively; a spraying distance is 80 mm.

In the step (3) of depositing the high-purity Y₂O₃ coating through cold spraying high-speed deposition technology, compressed air is used as working gas, a temperature of the compressed air is 500° C., a pressure of the compressed air is 2.0 MPa, and a spraying distance is 20 mm.

As shown in the drawing, a metal+Y₂O₃ transition layer 2 is coated on a substrate 1 through plasma spraying technology, a high-purity Y₂O₃ coating 3 is coated on the metal+Y₂O₃ transition layer 2 through cold spraying high-speed deposition technology. The (Al+Y₂O₃)/Y₂O₃ composite coating provided by the first embodiment has a porosity of 2.0% and an interface bonding strength between a ceramic coating and the substrate is 45 MPa.

### Second Embodiment

According to the second embodiment of the present invention, a method for preparing a protective coating on a 6061 aluminum alloy substrate for protecting an inner surface of a plasma etching chamber of an IC (integrated circuit) device comprises steps of:

(1) weighing 70 g of pure Al powders and 150 g of Y₂O₃ powders, mixing the pure Al powders with the Y₂O₃ powders, obtaining mixed micron (Al+Y₂O₃) powders after drying, weighing 200 g of high-purity Y₂O₃ powders with a purity of 99.99 wt. %, and drying the high-purity Y₂O₃ powders;

(2) preparing a (Al+Y₂O₃) coating with a thickness of 120 μm as a (Al+Y₂O₃) transition layer on the 6061 aluminum alloy substrate through plasma spraying technology by taking the mixed micron (Al+Y₂O₃) powders obtained by the step (1) as a raw material; and

(3) depositing a high-purity Y₂O₃ coating with a thickness of 170 μm on the (Al+Y₂O₃) transition layer obtained by the step (2) through cold spraying high-throughput deposition technology by taking the dried high-purity Y₂O₃ powders obtained by the step (1) as a raw material, so that a (Al+Y₂O₃)/Y₂O₃ composite coating as the protective coating is obtained.

In the step (2) of preparing the (Al+Y₂O₃) transition layer through plasma spraying technology, main working gas is argon, secondary working gas is hydrogen, powder feeding gas is nitrogen, and gas flow rates thereof are 25 mL/min, 200 mL/min and 30 mL/min, respectively; a spraying distance is 90 mm.

In the step (3) of depositing the high-purity Y₂O₃ coating through cold spraying high-throughput deposition technology, compressed air is used as working gas, a temperature of the compressed air is 550° C., a pressure of the compressed air is 2.2 MPa, and a spraying distance is 20 mm.

As shown in the drawing, a metal+Y₂O₃ transition layer 2 is coated on a substrate 1 through plasma spraying technology, a high-purity Y₂O₃ coating 3 is coated on the metal+Y₂O₃ transition layer 2 through cold spraying high-throughput deposition technology. The (Al+Y₂O₃)/Y₂O₃ composite coating provided by the second embodiment has a porosity of 1.8% and an interface bonding strength between a ceramic coating and the substrate is 60 MPa.

### Third Embodiment

According to the third embodiment of the present invention, a method for preparing a protective coating on a 6061 aluminum alloy substrate for protecting an inner surface of a plasma etching chamber of an IC (integrated circuit) device comprises steps of:

(1) weighing 40 g of pure Al powders and 120 g of Y₂O₃ powders, mixing the pure Al powders with the Y₂O₃ powders, obtaining mixed micron (Al+Y₂O₃) powders after drying, weighing 400 g of high-purity Y₂O₃ powders with a purity of 99.99 wt. %, and drying the high-purity Y₂O₃ powders;

(2) preparing a (Al+Y₂O₃) coating with a thickness of 160 μm as a (Al+Y₂O₃) transition layer on the 6061 aluminum alloy substrate through plasma spraying technology by taking the mixed micron (Al+Y₂O₃) powders obtained by the step (1) as a raw material; and

(3) depositing a high-purity Y₂O₃ coating with a thickness of 180 μm on the (Al+Y₂O₃) transition layer obtained by the step (2) through cold spraying high-speed deposition technology by taking the dried high-purity Y₂O₃ powders obtained by the step (1) as a raw material, so that a (Al+Y₂O₃)/Y₂O₃ composite coating as the protective coating is obtained.

In the step (2) of preparing the (Al+Y₂O₃) transition layer through plasma spraying technology, main working gas is argon, secondary working gas is hydrogen, powder feeding gas is nitrogen, and gas flow rates thereof are 30 mL/min, 180 mL/min and 25 mL/min, respectively; a spraying distance is 100 mm.

In the step (3) of depositing the high-purity Y₂O₃ coating through cold spraying high-speed deposition technology, compressed air is used as working gas, a temperature of the compressed air is 600° C., a pressure of the compressed air is 2.3 MPa, and a spraying distance is 20 mm.

As shown in the drawing, a metal+Y₂O₃ transition layer 2 is coated on a substrate 1 through plasma spraying technology, a high-purity Y₂O₃ coating 3 is coated on the metal+Y₂O₃ transition layer 2 through cold spraying high-speed deposition technology. The (Al+Y₂O₃)/Y₂O₃ composite coating provided by the third embodiment has a porosity of 1.7% and an interface bonding strength between a ceramic coating and the substrate is 55 MPa.

### Fourth Embodiment

According to the fourth embodiment of the present invention, a method for preparing a protective coating on a 6061 aluminum alloy substrate for protecting an inner surface of a plasma etching chamber of an IC (integrated circuit) device comprises steps of:

(1) weighing 40 g of pure Y powders and 120 g of Y₂O₃ powders, mixing the pure Y powders with the Y₂O₃ powders, obtaining mixed micron (Y+Y₂O₃) powders after drying, weighing 400 g of high-purity Y₂O₃ powders with a purity of 99.99 wt. %, and drying the high-purity Y₂O₃ powders;

(2) preparing a (Y+Y₂O₃) coating with a thickness of 120 μm as a (Y+Y₂O₃) transition layer on the 6061 aluminum alloy substrate through plasma spraying technology by taking the mixed micron (Y+Y₂O₃) powders obtained by the step (1) as a raw material; and

(3) depositing a high-purity Y₂O₃ coating with a thickness of 180 μm on the (Y+Y₂O₃) transition layer obtained by the step (2) through cold spraying high-speed deposition technology by taking the dried high-purity Y₂O₃ powders obtained by the step (1) as a raw material, so that a (Y+Y₂O₃)/Y₂O₃ composite coating as the protective coating is obtained.

In the step (2) of preparing the (Y+Y₂O₃) transition layer through supersonic plasma spraying technology, main working gas is argon, secondary working gas is hydrogen, powder feeding gas is nitrogen, and gas flow rates thereof are 30 mL/min, 180 mL/min and 25 mL/min, respectively; a spraying distance is 100 mm.

In the step (3) of depositing the high-purity Y₂O₃ coating through cold spraying deposition technology, compressed air is used as working gas, a temperature of the compressed air is 650° C., a pressure of the compressed air is 2.3 MPa, and a spraying distance is 20 mm.

As shown in the drawing, a metal+Y₂O₃ transition layer 2 is coated on a substrate 1 through plasma spraying technology, a high-purity Y₂O₃ coating 3 is coated on the metal+Y₂O₃ transition layer 2 through cold spraying deposition technology. The (Y+Y₂O₃)/Y₂O₃ composite coating provided by the fourth embodiment has a porosity of 1.5% and an interface bonding strength between a ceramic coating and the substrate is 35 MPa.

The results of the above embodiments show that, in the method for preparing the protective coating on the inner surface of the plasma etching chamber of the IC device, the plasma spraying technology and the cold spraying high-speed deposition technology are used to prepare the (metal+Y₂O₃)/Y₂O₃ composite coating. The coating, which is well bonded to the substrate, has the porosity of less than 2%, the interface bonding strength in a range of 30-80 MPa, and the thickness in a range of 100-400 μm. The coating is able to reduce the corrosion of corrosive gas to the etching chamber and the pollution of the plasma to the chip, and improve the service life of the plasma etching chamber in the process of producing the chip.

The above are detailed embodiments and specific operation processes based on the technical solutions provided by the present invention, but the protective scope of the present invention is not limited to the above embodiments.

1. A method for preparing a protective coating on a surface of key components and parts of an IC (integrated circuit) device based on plasma spraying technology and cold spraying technology, wherein:
the method adopts the plasma spraying technology and cold spraying high-speed deposition technology to form an evenly distributed protective coating on a surface of a plasma etching chamber of the IC device;
the protective coating, having a double-layer composite structure, comprises a metal+Y₂O₃ transition layer deposited by plasma spraying as a lower layer of the double-layer composite structure, and a high-purity Y₂O₃ ceramic coating coated on the metal+Y₂O₃ transition layer as an upper layer of the double-layer composite structure, the high-purity Y₂O₃ ceramic coating is formed by depositing Y₂O₃ ceramic powders on the metal+Y₂O₃ transition layer at high speed through cold spraying high-speed deposition;
the method comprises steps of drying metal powders and Y₂O₃ powders, respectively, and then obtaining a metal+Y₂O₃ layer by depositing the metal and Y₂O₃ powders on a substrate at high speed through supersonic plasma spraying technology, and then depositing high-purity Y₂O₃ powders on the metal+Y₂O₃ layer through cold spraying high-throughout deposition technology, so as to obtain the protective coating through controlling process parameters.

2. The method for preparing the protective coating on the surface of the key components and parts of the IC device based on the plasma spraying technology and the cold spraying technology according to claim 1, wherein the method comprises steps of:
(1) drying metal powders to be sprayed and Y₂O₃ powders to be sprayed,
respectively, wherein a purity of the metal powders and the Y₂O₃ powders is above 99.9 wt. %;
(2) preparing a metal+Y₂O₃ transition layer on a substrate through plasma spraying technology, which comprises:
placing the dried metal and Y₂O₃ powders into a powder feeder of a plasma spraying device, obtaining mixed powders after evenly mixing the dried metal and Y₂O₃ powders, melting and depositing the mixed powders on an inner surface of a plasma etching chamber through the plasma spraying technology, so as to obtain the metal+Y₂O₃ transition layer; and
(3) depositing a high-purity Y₂O₃ coating through cold spraying high-speed deposition technology, which is specifically embodied as depositing high-purity Y₂O₃ powders through the cold spraying high-speed deposition technology on the metal+Y₂O₃ transition layer obtained by the step (2), so as to obtain the high-purity Y₂O₃ coating,
whereby, a (metal+Y₂O₃)/Y₂O₃ composite protective coating is obtained.

3-6. (canceled)

7. The method for preparing the protective coating on the surface of the key components and parts of the IC device based on the plasma spraying technology and the cold spraying technology according to claim 1, wherein a porosity of the protective coating is below 2%, an interface bonding strength of the protective coating and the substrate is in a range of 20 to 100 MPa, and a thickness of the protective coating is in a range of 10 to 400 μm.

8. The method for preparing the protective coating on the surface of the key components and parts of the IC device based on the plasma spraying technology and the cold spraying technology according to claim 1, wherein the metal powders are at least one member selected from a group consisting of aluminum powders and yttrium powders.

9. The method for preparing the protective coating on the surface of the key components and parts of the IC device based on the plasma spraying technology and the cold spraying technology according to claim 2, wherein the metal powders are at least one member selected from a group consisting of aluminum powders and yttrium powders.

10. The method for preparing the protective coating on the surface of the key components and parts of the IC device based on the plasma spraying technology and the cold spraying technology according to claim 1, wherein a particle size of the metal powders and the Y₂O₃ powders is in a range of 1-50 μm.

11. The method for preparing the protective coating on the surface of the key components and parts of the IC device based on the plasma spraying technology and the cold spraying technology according to claim 2, wherein a particle size of the metal powders and the Y₂O₃ powders is in a range of 1-50 μm.

12. The method for preparing the protective coating on the surface of the key components and parts of the IC device based on the plasma spraying technology and the cold spraying technology according to claim 1, wherein the mixed powders are directly sprayed on the inner surface of the plasma etching chamber through supersonic plasma spraying technology, and simultaneously plasma spraying parameters are controlled, wherein main working gas used in the plasma spraying technology is argon, secondary working gas is hydrogen, powder feeding gas is nitrogen, and gas flow rates thereof are in a range of 10-80 mL/min, 5-220 mL/min and 5-80 mL/min, respectively; a spraying distance is in a range of 10-100 mm, so that the mixed powders are deposited on the inner surface of the plasma etching chamber, so as to obtain the evenly distributed metal+Y₂O₃ protective coating.

13. The method for preparing the protective coating on the surface of the key components and parts of the IC device based on the plasma spraying technology and the cold spraying technology according to claim 2, wherein the mixed powders are directly sprayed on the inner surface of the plasma etching chamber through supersonic plasma spraying technology, and simultaneously plasma spraying parameters are controlled, wherein main working gas used in the plasma spraying technology is argon, secondary working gas is hydrogen, powder feeding gas is nitrogen, and gas flow rates thereof are in a range of 10-80 mL/min, 5-220 mL/min and 5-80 mL/min, respectively; a spraying distance is in a range of 10-100 mm, so that the mixed powders are deposited on the inner surface of the plasma etching chamber, so as to obtain the evenly distributed metal+Y₂O₃ protective coating.

14. The method for preparing the protective coating on the surface of the key components and parts of the IC device based on the plasma spraying technology and the cold spraying technology according to claim 1, wherein the high-purity Y₂O₃ powders are deposited on the metal+Y₂O₃ transition layer obtained by the step (2) through the cold spraying high-speed deposition technology, and simultaneously cold spraying parameters are controlled, wherein compressed air is used as working gas, a temperature of the compressed air is in a range of 200 to 700° C., a pressure of the compressed air is in a range of 1.5 to 3.0 MPa, and a spraying distance is in a range of 10 to 60 mm, so that the high-purity Y₂O₃ powders are deposited on the metal+Y₂O₃ transition layer, so as to obtain the evenly distributed high-purity Y₂O₃ coating.

15. The method for preparing the protective coating on the surface of the key components and parts of the IC device based on the plasma spraying technology and the cold spraying technology according to claim 2, wherein the high-purity Y₂O₃ powders are deposited on the metal+Y₂O₃ transition layer obtained by the step (2) through the cold spraying high-speed deposition technology, and simultaneously cold spraying parameters are controlled, wherein compressed air is used as working gas, a temperature of the compressed air is in a range of 200 to 700° C., a pressure of the compressed air is in a range of 1.5 to 3.0 MPa, and a spraying distance is in a range of 10 to 60 mm, so that the high-purity Y₂O₃ powders are deposited on the metal+Y₂O₃ transition layer, so as to obtain the evenly distributed high-purity Y₂O₃ coating.
